(19) United States
(12) Patent Application Publication
(10) Pub. No.: US 2007/0007863 A1
(43) Pub. Date: Jan. 11, 2007

(54) Drilled multi-layer ultrasound transducer array

(75) Inventor: John Paul Mohr III, Aptos, CA (US)

Correspondence Address: SIEMENS CORPORATION;INTELLECTUAL PROPERTY DEPARTMENT, 170 WOOD AVENUE SOUTH, ISELIN, NJ, 08830, US

(73) Assignee: Siemens Medical Solutions USA. Inc.

(21) Appl. No.: 11/179,202

(22) Filed: Jul. 11, 2005

(51) Int. Cl. H01L 41/047

(52) U.S. Cl. 310/365; 29/25.35

(57) ABSTRACT

Vias are formed on each of a plurality of layers of transducer material prior to stacking. Using a desired electrode pattern or removal of strips, pairs of electrodes associated with each layer of transducer material are provided in a coplanar structure on each side of the layer. The smaller of the electrode structures on a given side is routed through the vias to a larger electrode structure. When the layers are stacked, the vias are used for interconnecting the electrodes between various layers. The electrical connection is provided through asperity contact.

### BACKGROUND

The present invention relates to multi-layer ultrasound transducer arrays. In particular, electrical interconnection of different electrodes of a multi-layer structure is provided.

In multi-layer ultrasound transducer arrays, a plurality of layers of transducer material is stacked together. Electrodes separate each layer of transducer material. Every other electrode is connected with the signal source and the remaining electrodes are connected with a ground potential. Providing for electrical interconnections between the different electrodes of the layers may be difficult. For example, multi-dimensional transducer arrays provide limited access to the electrodes of interior layers of interior elements.

U.S. Pat. No. 6,664,717 discloses one embodiment of a multi-layer, multi-dimensional transducer array. By forming different layers with a same or similar electrode configuration, the layers may be stacked together to provide the desired electrical interconnections. Electrical contact is made through an asperity contact.

Other approaches use vias. For example, tape cast sheets of piezoelectric material are screen printed. An electrode pattern is printed on the sheets. The sheets are then stacked. The stack is fired or sintered. Vias are then formed through the stack for electrical interconnection. However, tape casting and associated sintering have poor dimensional control. The electrode pattern may be warped or shifted to undesired locations, causing misalignment with the later formed vias.

### BRIEF SUMMARY

By way of introduction, the preferred embodiments described below include elements, arrays and methods of manufacturing ultrasound transducer arrays. Vias are formed on each of a plurality of layers of transducer material prior to stacking. Using a desired electrode pattern or removal of strips, pairs of electrodes associated with each layer of transducer material are provided in coplanar arrangements on each side of the layer. The smaller of the electrode structures on a given side is routed through or connects with the vias. When the layers are stacked, the vias and coplanar arrangement are used for interconnecting the electrodes between various layers. The electrical connection is provided through asperity contact.

In a first aspect, an element is provided for use in an ultrasound transducer array. A plurality of electrodes is stacked with a plurality of layers of transducer material in asperity contact. At least one via for electrically connecting an electrode of the plurality of electrodes on a first layer of the plurality of layers extends through a second layer of the plurality of layers.

In a second aspect, a multi-dimensional ultrasound transducer array is provided. A plurality of elements in a multi-dimensional distribution each has at least two layers of transducer material. A first electrode arrangement electrically separates or is electrically separate from a second electrode arrangement. The two arrangements are provided on each of the elements and, at least in part, are coplanar on a same side of at least one of the two layers of transducer material. A via includes at least part of the first electrode arrangement.

In a third aspect, a method is provided for manufacturing a multi-dimensional ultrasound transducer array. A plurality of vias is formed on different layers of transducer material. At least one conductor is formed on each of the layers of transducer material. The layers of transducer material are stacked after forming the plurality of vias.

The present invention is defined by the following claims, and nothing in this section should be taken as a limitation on those claims. Further aspects and advantages of the invention are discussed below in conjunction with the preferred embodiments.

### BRIEF DESCRIPTION OF THE DRAWINGS

The components and the figures are not necessarily to scale, emphasis instead being placed upon illustrating the principles of the invention. Moreover, in the figures, like reference numerals designate corresponding parts throughout the different views.

FIG. 1 is a flowchart diagram of one embodiment of a method for manufacturing a multi-dimensional ultrasound transducer array;

FIG. 2 is a top view of one embodiment of a layer of transducer material with vias;

FIG. 3 is a top and bottom view of a portion of a layer of transducer material with electrodes having electrical isolations associated with vias;

FIG. 4 is a side view of one embodiment of an electrode interconnection structure within an element of an ultrasound transducer array;

FIG. 5 is a top view of one embodiment of a multi-dimensional transducer array with multi-layer elements; and

FIG. 6 shows one example of interlayer electrical connection made by asperity contact held in place by polymeric bonding material disposed between the plates.

### DETAILED DESCRIPTION OF THE DRAWINGS AND PRESENTLY PREFERRED EMBODIMENTS

A transducer array of one or more elements has one or more discrete multi-layered piezo-ceramic elements. The array is formed by stacking drilled, metallized and patterned piezoelectric plates. The plates are aligned relative to each other and bonded together. Electrical continuity between plates is achieved by asperity contact of mating electrodes and vias, and maintained by a polymeric layer, such as epoxy adhesive, disposed between the plates. With or without an additional conductive matching layer for connection to a common ground, the stack of plates is diced in orthogonal directions to define and electrically isolate individual elements from each other. Electrical connectivity to one or both electrode arrangements may be provided on the top or bottom of the stack. Coplanar presentation of the hot and neutral electrodes is provided on the top or bottom surfaces of the stack. Different layers may be associated with different hot electrodes or arrangements, allowing the use of different receive or transmit signals for different layers.

FIG. 1 shows one embodiment of a method for manufacturing a multi-dimensional ultrasound transducer array. The method may alternatively be used for manufacturing a one-dimensional or a single element transducer. Additional, different or fewer acts may be provided than shown in FIG. 1. For example, the acts are performed without act 20. As another example, assembling stacked layers with additional transducer components, such as one or more matching layers and/or a backing block, is provided. The acts may be performed in the order shown or in a different order.

In act 12, a plurality of vias is formed on each of at least two layers of transducer material. The transducer material includes a piezoelectric or composite piezoelectric plate. Each layer of transducer material corresponds to an entire array of elements, but may correspond to just a portion of the array. The layer 22 of transducer material is ground or otherwise formed for flatness or to a shape such that the layers 22 mate with asperity contact.

The vias are through holes extending entirely through each plate. The vias are formed by drilling, such as with a mechanical or laser drill, such as a very short wavelength laser. In one embodiment, the transducer plate 22 is formed with the vias 28 by injection molding. Alternatively, chemical etching is provided to form the vias.

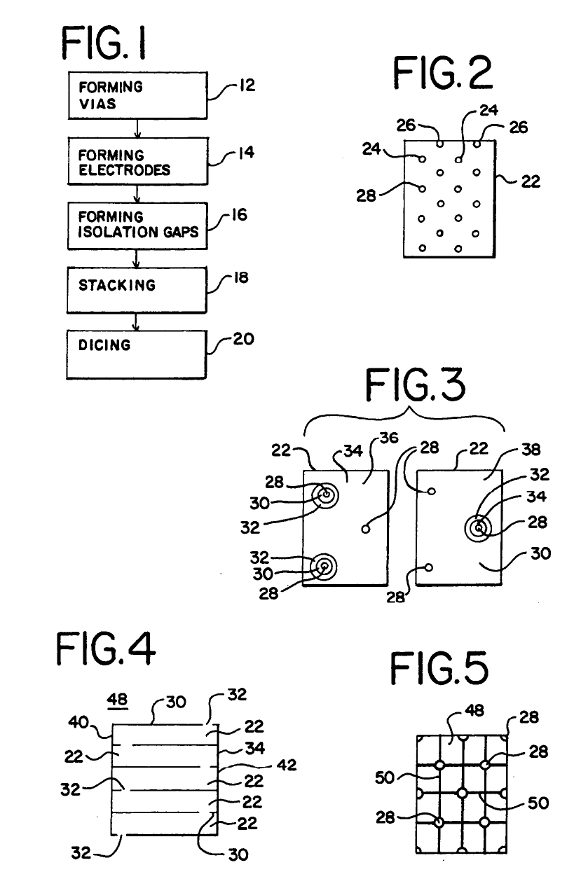

The vias are formed with a spacing of about twice an element pitch. FIG. 2 shows a transducer layer 22 or portion of a transducer layer 22 with a plurality of rows 24, 26 of vias 28. The vias 28 of each adjacent row 24, 26 are offset from each other, such that one set of rows 24 has a common vertical position of the vias 28 as shown in FIG. 2 and the other set of row 26 has common vias 28 along a vertical dimension. Any pitch may be provided, such as a pitch of 500 micrometers on a plate having a 65 micrometer thickness. The vias 28 are of any desired dimension, such as 100 micrometers in diameter. Larger or smaller relative via sizes to element pitch may be provided. In alternative embodiments, the vias 28 have a greater or lesser spacing than twice the element pitch.

In act 14, a conductor is formed on each of the layers of transducer material. For example, each plate of piezoelectric material is completely coated with a conductive material, such as a copper, silver, aluminum or other electrically conductive material. The coating is performed with sputtering, electro-less deposition, electroplating or other now known or later developed techniques. The coating covers the top and bottom surfaces of each plate as well as the sidewalls of the vias 28. The vias 28 have an aspect ratio of about 1:1.5, and may be easily coated with an electrode. Different aspect ratios may be provided. Alternatively, the coating fills the vias 28 with conductive material. The side edges of the layer 22 may or may not be coated. Once separated or isolated in act 16, the conductor forms two or more electrodes on the layer 22 of transducer material. Different ones of the vias 28 may be used or associated with different ones of the electrodes on given transducer layer 22.

In act 16, isolation gaps are formed. As shown in FIG. 3, an isolation gap 32 is formed around each of the vias 28. The isolation gap 32 is formed by etching, grinding or other now known or later developed technique. To form the isolation gaps 32 by removing electrode or conductor material, a very short wavelength laser is used in one embodiment. In alternative embodiments, the isolation gaps 32 are formed in act 16 as part of forming the electrodes 14, such as depositing the conductive material with patterning. The conductor deposited on the sides or edges of each of the plates 22 is removed by grinding, etching or other technique. In alternative embodiments, any conductor is allowed to remain on the edges of the plate 22 of transducer material.

The isolation gaps 32 leave a portion of a first electrode 30 adjacent to the via 28 and extending into and through the via 28. Another portion of a different electrode 34 covers the remaining surface area of the piezoelectric plate 22. Since the first portion 30 of one electrode is on a same surface as the other electrode 34, both electrodes 30, 34 are coplanar or provided on a same surface. As shown in FIG. 3, the isolation gaps 32 are circular strips, providing a circular portion 30 of one electrode adjacent to the via 28. Other shapes may be provided, such as polygonal shapes. In one embodiment, the isolation gap 32 is about 25 micrometers in thickness, but greater or lesser separation of the two electrodes 30, 34 from each other may be provided.

FIG. 3 shows formation of the isolation gaps 32 differently for a top and bottom surfaces 36 and 38. The isolation gaps 32 are formed around the vias 28 for every other row 24 of vias 28 on one side 36. For example, the rows 24 correspond to odd rows. On an opposite side 38, the even rows 26 of vias 28 are surrounded by isolation gaps 32. The other vias 28 on the top and bottom sides 36, 38 are maintained free of isolation gaps 32.

After formation of the isolation gaps 16, a plurality of separate layers 22 of transducer material have corresponding vias 28 and isolation gaps 32. Each layer 22 is separately manufactured. To avoid destruction of the layers 22, a carrier or other plate is used for supporting the layer 22, during processing and transport. After forming the isolation gap 32 in act 16, each layer 22 includes two different electrodes 34, 30. Each of the electrodes 30, 34 are exposed on both top and bottom surfaces 36, 38. The portions of each electrode 30, 34 are connected between the surfaces 36, 38 by one or more vias 28. Before or after dicing or kerfing, the electrodes 30, 34 are electrically isolated from each other.

In one embodiment, each of the layers 22 for a given transducer stack has a similar or identical structure. In alternative embodiments, one or both of the top and bottom layers 22 to be used in the transducer stack has a different arrangement of isolation gaps 32. For example, isolation gaps 32 are formed to prevent exposure of one electrode on one of the surfaces. As a result, a flexible circuit used for connecting signals to the transducer array may connect with only one electrode arrangement. For use on a top surface, a grounding plane may connect with only one of the two electrodes 30, 34 on the layer. In one embodiment, both the top and bottom layers 22 have only one pole or type of electrode 30, 34 showing, such as a ground electrode for the top surface of the top layer 22 and a signal electrode for the bottom surface of the bottom layer 22. In another embodiment, the top layer 22, the bottom layer 22 or both the top and bottom layer 22 have electrodes 30, 34 of both poles exposed on both top and bottom surfaces of the layer 22. In yet another embodiment, one or more of the layers 22 within the stack or between other layers 22 are formed to avoid interconnection of the signal electrodes between the layers 22. For example, a stack of six layers 22 has two different signal electrodes, one formed for the upper three layers 22 and another formed for the lower three layers 22. The junction between the middle two layers provides connection of grounding electrodes but not signal electrodes.

In act 18, the layers 22 formed as described above are stacked. The stacking occurs after forming the vias 28 and isolation gaps 32. The vias 28 or electrodes 30, 34 of each of the layers 22 are aligned. By aligning, the first type of electrode 30, 34 of different layers 22 is mated to the same type of electrode 30, 34 of other layers 22. FIG. 4 shows five layers 22 stacked together. As stacked, the electrodes 30, 34 are mated together between each layer 22 to provide interconnection throughout the stack. The isolation gaps 32 separate the two electrodes 30, 34 from each other. A majority of one type of electrode 30, 34 is provided between each of the layers 22. A minority of the other type of electrode 30, 34 is provided. The electrical connections through the via 28 represented by 40 and 42 interconnect the various minority or majority portions of the same electrode 30, 34 to each other throughout the layers 22.

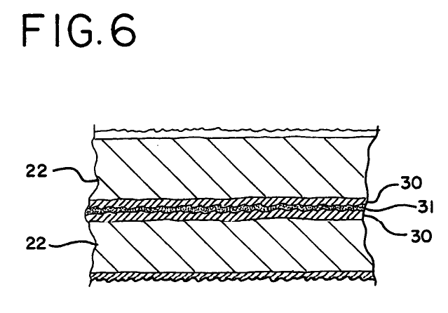

To maintain the asperity contact of the layers of transducer material, the stacked layers 22 are bonded together. With strong electrode adhesion and bonding under pressure, interlayer 22 electrical connections are formed and held or maintained with asperity contact. FIG. 6 shows epoxy or other bonding agent 31 holds the layers 22 adjacent to each other with the electrodes 30, 34 mated to provide electrical separation of the two types of electrodes 30, 34. The asperity contact is provided without firing, reducing the likelihood of dimensional distortion between the layers 22. In alternative embodiments, heat is applied to speed bonding by the bonding agent.

In an alternative embodiment than shown in FIG. 4, the ground electrode 30 extends or connects with all the layers 22. The signal electrode 34 is divided into two electrically separate electrodes, one for upper layers 22 and another for lower layers 22. Using vias 28, the different signal electrodes 34 are addressable from the top, bottom or both top or both bottom of the stack. For example, the different signal electrode arrangements 30, 34 are used as disclosed in U.S. Pat. No. 6,409,667, the disclosure of which is incorporated herein by reference. One subset of layers may be used for transmit or receive, and a different subset or all layers 22 are used for the associated receive or transmit operations. By providing a center plate or layer 22 free of electrode material within the vias 28, the signal electrodes between the two subsets of layers are separated. Both layers 22 adjacent to a separation boundary avoid routing the signal electrode to the adjacent layer.

The stacked layers 22 may also be stacked with a backing block and one or more matching layers before or after bonding. The matching layers may be conductive or non-conductive. A flexible circuit for signal connection and a ground plane connection are also stacked adjacent to a top surface, bottom surface or both top and bottom surfaces of the transducer stack.

In one embodiment, the backing block is a Z-axis conducting backing block. For example, a plurality of conductors route along the Z-axis to one or more pads or bumps provided on the top of the backing block for connecting with different ones of the elements 48. Alternatively, a flexible circuit extends to the side to route electrical signals from the various elements without the Z-axis backing. In one embodiment of the Z-axis backer, a plurality of plates of backing material has grooves formed at an element pitch. The grooves are then metallized. The metallized grooves act as the Z-axis conductors. By stacking the plates along an elevation or an azimuth dimension, the plurality of Z-axis conductors at the element pitch for the array are provided. Electrodes or bumps are then formed on the exposed ends of the Z-axis conductors for connection with flexible circuits and the elements of the transducer.

In act 20, the layers of transducer material 22 are diced. FIG. 5 shows formation of kerfs 50 to provide elements 48. The kerfs 50 are filled with air or gas, or epoxy, or other now known or later developed kerf filling material. The kerfs 50 extend through the vias 28, providing two vias 28 for each element 48. The kerfs 50 are diced at an element pitch. Where the vias 28 are provided at twice the element pitch, the pattern in FIG. 5 is provided. Different patterns in same or different pitches for the vias 28 and/or kerfs 50 may be provided. Dicing the kerfs 50 removes conductive material within the kerf 50. A portion of the vias 28 is free of the dicing, maintaining the electrical connection in between the different layers of each element 48. For example, FIG. 4 represents the electrical interconnections 40 and 42 provided in a single element 48 in portions of two different vias 28 on opposite sides of the element 48. While shown on opposite corners of each element 48, the vias 28 may be on a same, adjacent or opposite sides at the corners or positions not at the corners. The fringe effects of wraparound portions of the electrode on the sides of each element are minimized by placing the conductors in the vias rather than an entire side and may be even further minimized by positioning the vias 28 in the corners.

FIG. 4 shows one embodiment of an element 48 for use in an ultrasound transducer array, such as a multi-dimensional ultrasound transducer array. The element 48 is manufactured using the method described in FIG. 1 or a different method. The element 48 includes a plurality of layers 22 of transducer material, a plurality of electrodes 30, 34, and at least one via 28, such as associated with conductors 40 or 42. Additional, different or fewer components may be provided, such as including one or more conductive or non-conductive matching layers, a grounding plane, a backing block, flexible circuit, and/or conductors for routing signals to or from the element 48.

The electrodes 30, 34 are stacked with the layers 22 of transducer material in asperity contact. The stacking is performed along a range or Z-axis. Each layer 22 of transducer material is sandwiched between two majority electrodes, such as one grounding electrode 30 and a one-signal electrode 34. Between each layer 22 of transducer material is one or more electrodes 30, 34. For example, a separate electrode 30 is formed on each of the layers 22. When stacked, the two electrodes 30 are in contact. The layers 22, such as from transducer layer 22 to an electrode 30, 34 or between pairs of electrodes 30, 34, are positioned in asperity contact. Bonding material holds the stack together, providing electrical conductivity between the layers.

One or more vias 28 electrically connect the electrodes 30, 34 of the layers 22 together. For example, the conductors 40 positioned in a via 28 connect an electrode of one layer 22 through a second layer 22. The element 48 includes two arrangements of electrodes 30, 34 where each arrangement 30, 34 includes a majority electrode between every other layer 22.

The conductors 40, 42 are positioned for the electrical interconnections in different vias 28. The vias 28 are an entire cylinder or only a portion of a cylinder, such as a quarter or less of via 28 due to dicing into the via 28 along orthogonal lines. Greater or lesser portions of an entire via 28 may be used for each conductor 40, 42 for interconnecting layers 22. Since two electrode arrangements 30, 34 are provided, two different vias 28 and associated interconnecting electrodes 40, 42 are used in each element 48. The vias 28 are on opposite sides of the element 48, such as at opposite corners. To provide or more likely assure electrical interconnection through the vias 28, at least a minority electrode is formed separated from a majority electrode by the isolation gap 32 between the layers 22 of transducer material. The majority and minority electrodes are coplanar, allowing contact for electrical conductivity through asperity contact. The top of the top layer 22 or the bottom of the bottom layer 22 or both surfaces also include majority and minority electrodes. Alternatively, the top or bottom of the stacks is associated with a single electrode arrangement 30, 34.

A plurality of the elements 48 are positioned adjacent to each other in at least one dimension or spaced apart for a sparse array. For example, FIG. 5 shows part of a multi-dimensional array of elements 48. A plurality of elements 48 are spaced along azimuth and elevation dimensions. Each of the elements 48 includes a plurality of layers 22 of transducer material along a range or Z-dimension. Each of the elements 48 includes two or more arrangements of electrodes for transducing between acoustic and electrical energies. For electrical connectivity through asperity contact, majority and minority portions of an electrode arrangement are provided between each of the layers 22. A coplanar arrangement allows for electrical connectivity of the different arrangements between the layers 22. The signal electrodes of each element 48 are separately routed to an imaging system. Alternatively, one or more elements 48 are electrically connected with a different element 48 for receiving or transmitting electrical signals. In one embodiment, a common ground plane connects to all of the elements 48.

While the invention has been described above by reference to various embodiments, it should be understood that many changes and modifications can be made without departing from the scope of the invention. It is therefore intended that the foregoing detailed description be regarded as illustrative rather than limiting, and that it be understood that it is the following claims, including all equivalents, that are intended to define the spirit and scope of this invention.

1. An element for use in an ultrasound transducer array, the element comprising:
a plurality of layers of transducer material;
a plurality of electrodes stacked with the layers of piezoelectric material in asperity contact; and
at least one via for electrically connecting a first electrode of the plurality of electrodes on a first layer of the plurality of layers through a second layer of the plurality of layers.

2. The element of claim 1 wherein each of the plurality of layers includes two electrodes, one of the electrodes of each layer connected through asperity contact with one of the electrodes of an adjacent layer.

3. The element of claim 1 wherein the layers of piezoelectric material are held in asperity contact by bonding material.

4. The element of claim 1 wherein the at least one via comprises a quarter via with conductor material connected with the first electrode.

5. The element of claim 1 wherein the at least one via comprises first and second vias on opposite sides of the element, the first via connecting the first electrode through the second layer and the second via connecting a third electrode on the second layer through the first layer of piezoelectric material.

6. The element of claim 1 wherein at least one of the plurality of layers of piezoelectric material includes at least two coplanar, electrically separated electrodes on a same surface.

7. The element of claim 6 wherein the at least one of the plurality of layers of piezoelectric material comprises a top, a bottom or top and bottom layers, and wherein the same surface is a top surface of the top layer or a bottom surface of the bottom layer.

8. The element of claim 1 wherein the at least one via comprises first and second vias, the first via electrically connected with every other electrode of the plurality of electrodes and the second via electrically connected with every other electrode of the plurality of electrodes different than the electrodes electrically connected with the first via.

9. The element of claim 1 wherein the first electrode is a first signal electrode electrically disconnected from a second signal electrode, the first and second signal electrodes corresponding to different ones of the plurality of layers of piezoelectric material.

10. A multi-dimensional, ultrasound transducer array, the array comprising:
a plurality of elements in a multi-dimensional distribution, each element having at least two layers of transducer material;
a first electrode arrangement electrically separate from a second electrode arrangement, the first and second electrode arrangements being on each of the elements and being, at least in part, coplanar on a same side of at least one of the at least two layers of transducer material; and
at least one via having part of the first electrode arrangement.

11. The array of claim 10 wherein the at least two layers of transducer material connect with asperity contact and are held in place by bonding material.

12. The array of claim 10 wherein the at least one via comprises a partial via with conductor material of the first electrode arrangement for each of the elements.

13. The array of claim 10 wherein the at least one via comprises first and second vias on opposite sides of each element, the first via having part of the first electrode arrangement and the second via having part of the second electrode arrangement.

14. The array of claim 10 wherein the same side is a top surface of a top layer of the at least two layers of transducer material or a bottom surface of a bottom layer of the at least two layers of transducer material.

15. The array of claim 10 wherein the at least one via comprises first and second vias on each element, the first via having part of the first electrode arrangement and the second via having part of the second electrode arrangement, the first electrode arrangement having a first majority electrode for each of the at least two layers of transducer material and the second electrode arrangement having a second majority electrode for each of the at least two layers of transducer material.

16. The array of claim 10 further comprising a third electrode arrangement electrically separate from the first and second electrode arrangements, the second electrode arrangement corresponding to a grounding electrode and adjacent all of the at least two layers of transducer material, and the first and second electrode arrangements corresponding to first and second signal electrode arrangements for different ones of the layers of transducer material.

17. A method of manufacturing a multi-dimensional, ultrasound transducer array, the method comprising:
forming a plurality of vias on at least first and second layers of transducer material;
forming at least a first conductor on each of the first and second layers of transducer material;
stacking the first and second layers of transducer material after forming the plurality of vias; and
forming an isolation gap in the first conductor around each of the vias, the isolation gap leaving a first electrode portion adjacent the via and a second electrode portion spaced from the via by the first electrode portion and the isolation gap, the first and second electrode portions being coplanar.

18. The method of claim 17 wherein forming the plurality of vias comprises drilling the vias with a spacing of twice an element pitch.

19. The method of claim 17 wherein forming the at least a first conductor comprises coating the first and second layers of transducer material after forming the vias, the coating including conductive material within the vias.

20. (canceled)

21. The method of claim 17 wherein the at least first conductor comprises first and second electrodes on each of the first and second layers, the first electrode portion being part of the first electrode and the second electrode portion being part of the second electrode, the first electrode electrically isolated from the second electrode.

22. The method of claim 17 wherein forming the isolation gap comprises forming the isolation gaps around vias in even rows on a first side of the first and second layers and forming the isolation gaps around vias in odd rows on a second, opposite side of the first and second layers.

23. The method of claim 17 wherein the at least a first conductor comprises first and second electrodes on each of the first and second layers of transducer material, a first set of vias including the first electrode and a second set of vias including the second electrode;
wherein stacking comprises:
aligning the vias of the first and second layers of transducer material, mating the first electrode of the first layer of transducer material with the first electrode of the second layer of transducer material and the second electrode of the first layer of transducer material with the second electrode of the second layer of transducer material, and bonding the first and second layers of transducer material in asperity contact.

24. The method of claim 18 further comprising:
dicing the first and second layers of transducer material at an element pitch such that each element is associated with two of the vias.

25. The method of claim 17 wherein stacking comprises stacking with the first transducer layer in a first subset of layers and the second transducer layer in a second subset of layers, the first subset having a first signal electrode, the second subset having an electrically separate, second signal electrode, and the first and second subsets having a common ground electrode arrangement.
